(19) United States
(12) Patent Application Publication
(10) Pub. No.: US 2008/0011602 A1
(43) Pub. Date: Jan. 17, 2008

(54) Deposition apparatus and deposition method

(75) Inventors: Hidenobu Ota, Suwa (JP); Toshihiro Terasawa, Chigasaki (JP); Saburo Shimizu, Chigasaki (JP); Naruyasu Sasaki, Chigasaki (JP); Koichi Hanzawa, Chigasaki (JP); Takafumi Matsumoto, Chigasaki (JP)

Correspondence Address: HARNESS, DICKEY & PIERCE, P.L.C., P.O. BOX 828, BLOOMFIELD HILLS, MI, 48303, US

(73) Assignee: Seiko Epson Corporation & ULVAC, Inc.

(21) Appl. No.: 11/827,427

(22) Filed: Jul. 11, 2007

(30) Foreign Application Priority Data
Jul. 14, 2006 (JP) 2006-194485
Jan. 29, 2007 (JP) 2007-018347

(51) Int. Cl. C23C 14/34

(52) U.S. Cl. 204/192.1; 204/298.11

(57) ABSTRACT

A shield for controlling film thickness is arranged between a substrate and a target. The shield includes an aperture being narrow at a target side and wide at a side opposite to the target. Since the density of sputtered particles decreases away from the target, a portion of the substrate that is far from the target is exposed to low-density sputtered particles for a long time, and a portion of the substrate that is near the target is exposed to high-density sputtered particles for a short time, whereby a film of even thickness distribution is formed on a deposition face of the substrate.

### CROSS-REFERENCE TO RELATED APPLICATION

This application claims priority to Japanese Patent Application Nos. 2006-194485, filed Jul. 14, 2006, and 2007-018347, filed Jan. 29, 2007, the contents of which are incorporated herein by reference.

### BACKGROUND

1. Technical Field

The present invention relates to a deposition technique, and more particularly relates to a deposition technique used in deposition on a large substrate.

2. Related Art

apparatus, a source, from which vapor of deposition material or sputter particles of deposition material and the like are released, is arranged in a vacuum chamber. The particles released from the source of the deposition material are applied to a deposition face of a substrate arranged in the vacuum chamber, and a thin film of the deposition material grows on the deposition face.

When growing the thin film of the deposition material, if the substrate is tilted such that the particles of the deposition material are diagonally incident on the deposition face, crystals of the deposition material having a constant orientation are grown on the deposition face. As a result, it is possible to obtain a film having functions (e.g., liquid crystal orientation) that originate from its crystal orientation (see for example Unexamined Japanese Patent Application, First Publication No. S63-89656).

However, when particles released from the source axes diagonally incident on the deposition face, the amount of deposition material delivered to positions on the deposition face that are near the source is comparatively greater than positions that are far away from the source, whereby the distribution thickness of the film formed on the deposition face is uneven. Difference in film thickness distribution is particularly considerable when a large substance is used.

### SUMMARY

An advantage of some aspects of the invention is to provide a deposition apparatus capable of depositing a thin film with even thickness distribution.

According to a first aspect of the invention, there is provided a deposition apparatus that uses sputtering to diagonally impact a substrate with particles emitted from a target and thereby forms a film on the substrate, including: a first shield that blocks part of particles incident to the substrate; a first aperture through which the particles pass, provided in the first shield, and being narrow near the target and wider away from the target; and a moving apparatus that relatively moves between the substrate and the first aperture in a direction transverse to a longitudinal axis of the first aperture.

In an embodiment of the first aspect, the first aperture can have at least a shape substantially similar to an incidence region at the deposition face of the substrate.

In an embodiment of the first aspect, the first aperture can have a width being gradually extending along a direction away from the target.

In the first aspect, it is preferable that an angle between via line segment that connects the target and the substrate, and the deposition face of the substrate, be no greater than 15°.

In the first aspect, it is preferable that the angle between a line segment that connects the target and the substrate, and the deposition face of the substrate, be no greater than 10°.

In the first aspect, it is preferable that the angle between the line segment and the deposition face is preferably no less than 1°.

In this case, it is preferable that the angle between the line segment and the deposition face be no less than 3°.

In an embodiment of the first aspect, the deposition apparatus can also include a second shield that controls incidence angle of the particle, arranged between the first shield and the target; and a second aperture provided in the second shield, and through which particles whose angle of incidence to the substrate is no greater than 15° pass.

In this case, it is preferable that the second aperture allow particles whose expected angle of incidence, being a value obtained by subtracting a minimum value from a maximum value of the incidence angle, is no greater than 10°, to pass.

According to a second aspect of the invention, there is provided a deposition method of using sputtering to diagonally impact a substrate with particles emitted from a target and thereby form a film on the substrate, including: arranging a first shield between the target and the substance, the first shield having a first aperture which is narrow near the target and wider away from the target; and relatively moving between the substrate and the fit aperture in a direction transverse to a longitudinal axis of the first aperture.

In the second aspect, it is preferable that the maximum incidence angle when particles from the target are incident to the substrate be no greater than 15°.

In the second aspect, it is preferable that the maximum incidence angle when particles from the target are incident to the substrate be no greater than 10°.

In the second aspect, it is preferable that the maximum incidence angle be no less than 1°.

In the second aspect, it is preferable that the maximum incidence angle be no less than 3°.

In the second aspect, it is preferable that the expected incidence angle, being a value obtained by subtracting a minimum incidence angle when the particles are incidence to the substrate from the maximum incidence angle, be no greater than 10°.

According to the first and second aspect of the present invention, even when the deposition face of the substrate has a large area, a thin film having even thickness distribution can be formed. That is, since the fixture aperture is narrow near the target where high-density sputter particles reach, and wide far away from the target where low-density sputter particles reach, if the substrate and the first aperture are relatively moved in a direction across the longitudinal axis of the first aperture, approximately equal quantities of sputter particles reach the target-side portion of the substrate and the opposite side portion.

### BRIEF DESCRIPTION OF THE DRAWINGS

FIG. 1 is a cross-sectional view for explanation of one example of a deposition apparatus used in the present invention.

FIG. 2A is a plan view of the positional relationship between a shield for controlling film thickness and a substrate.

FIG. 2B is a cross-sectional view of the positional relationship between a shield for controlling film thickness and a substrate.

### DESCRIPTION OF EXEMPLARY EMBODIMENTS

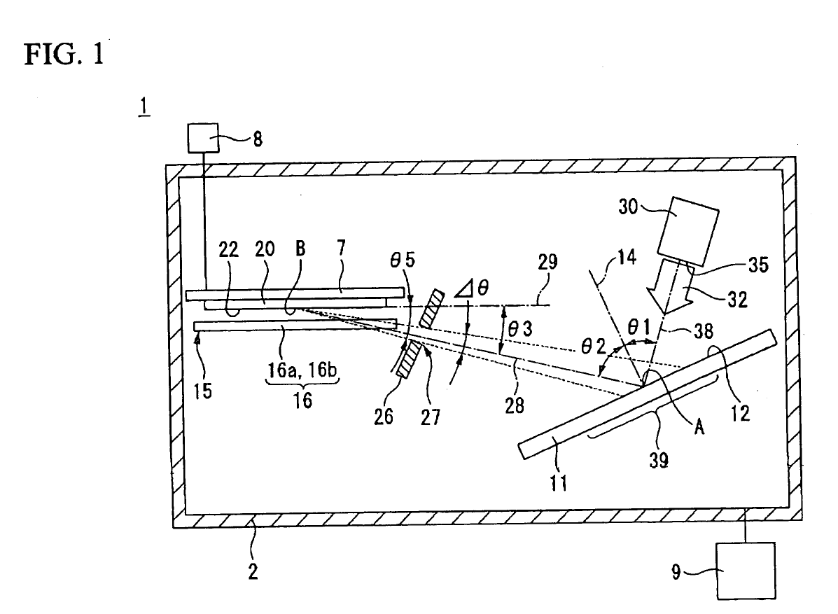

In FIG. 1, reference symbol 1 shows one example of a deposition apparatus as a sputtering system.

The deposition apparatus 1 includes a vacuum chamber 2, which an evacuating system 9 is connected to. When the evacuating system 9 is activated, an internal part of the vacuum chamber 2 is evacuated and a vacuum atmosphere is formed therein.

A plate-like target 11 is disposed inside the vacuum chamber 2. When the vacuum chamber 2 is evacuated by the evacuating system 9, the target 11 is placed in the vacuum atmosphere.

The deposition apparatus 1 includes an ion gun 30 which is arranged with an ejection hole 35 at a diagonal position to the target 11 in the vacuum chamber 2 such that the ejection hole 35 is facing a top face (spur face) 12 of the target 11. Ions (e.g. Ar ions) generated in the ion gun 30 are released in beam state from the ejection hole 35, and an ion beam 32 is diagonally incident on the sputter face 12.

The ion beam 32 has a predetermined width (e.g. half bandwidth of 30 mm). When the ion beam 32 is incident on the sputter face 12, the ion beam 32 irradiates a region (irradiation region 39) whose size is proportionate to the beam width and sputtered particles are released from the sputter face 12 to the internal part of the vacuum chamber 2.

A substrate holder 7 is provided inside the vacuum chamber 2. When a substrate 20 is inserted into the vacuum chamber 2 and held by the substrate holder 7, the substrate 20 is located at a diagonal position to the target 11. The substrate 20 is arranged at adjacent the same side (sputter face 12 side) of the target 11 as the ejection hole 35 of the ion gun 30, and the position of the substrate 20 is opposite the ejection hole 35 with the center of the target 11 therebetween. When sputtering is performed by irradiating the ion beam 32 from the ejection hole 35, sputter particles from the target 11 fly toward the substrate 20.

A shield 16 for controlling film thickness is arranged between the substrate 20 and the target 11, at a position near the substrate 20. In the embodiment, the shield 16 includes two shield plates 16a and 16b, arranged within a same plane and having edges facing each other with a space therebetween.

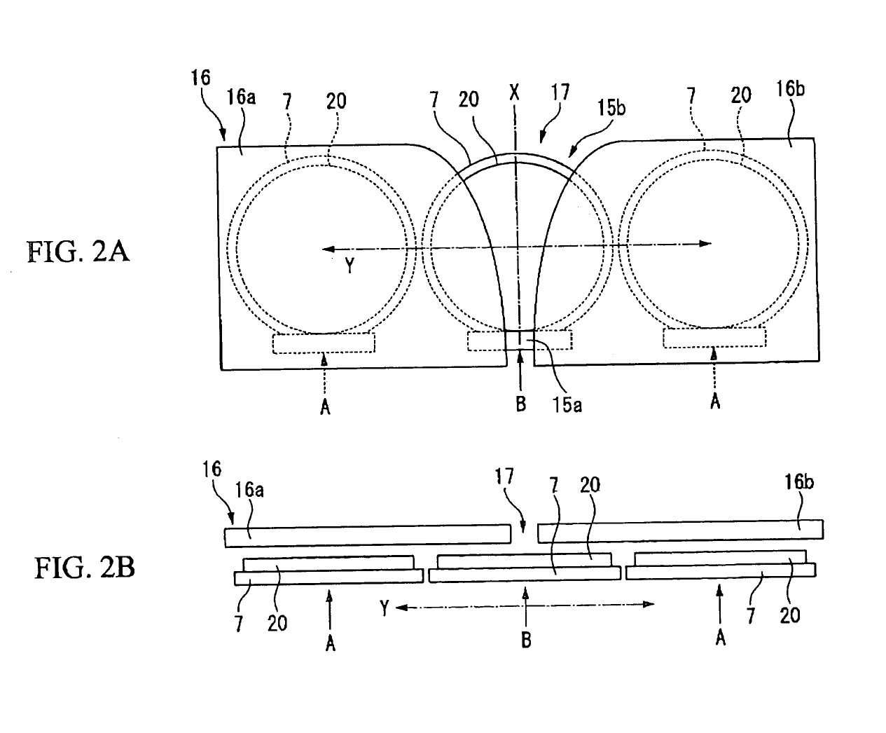

FIG. 2A is a plan view of the positional relationship between the shield plates 16a and 16b and the substrate 20. FIG. 2B is a cross-section view of the positional relationship. The shield plates 16a and 16b respectively have two ends of the mutually facing edges. In the mutually facing edges, end portions further from the target 11 are respectively rounded, and the interval between them is wider than that between the other end portions that are nearer the target 11. That is, each portion of the mutually facing edges further from the target 11 has a contour having a curvature.

In other words, the shield 16 has an aperture 17 for controlling film thickness, which is formed by the space between the mutually facing edges of the shield plates 16a and 16b. The space has a generally long thin cross-sectional shape. That is, the aperture 17 has a longitudinal axis along a direction perpendicular to the arranging direction of the shield plates 16a and 16b. Furthermore, the aperture 17 has at least a shape substantially similar to an incidence region, onto which the sputtered particles incident, of a deposition face 22 of the substrate 20. The width of the aperture 17 gradually widens as its distance from the target 11 increases. That is, the width of the aperture 17 is gradually extending along a direction away from the target 11.

In FIG. 2A, reference symbols 15a and 15b respectively represent a narrow end and a wide end of the aperture 17, and reference symbol X represents a center line of the aperture 17 that runs through the narrow end 15a and the wide end 15b. As shown in FIG. 2A, the length of the aperture 17 along the center line X is greater than the width of the narrow end 15a. Furthermore, at least a portion of the aperture 17 that is near the target 11 has a slit shape.

The substrate holder 7 is electrically connected to a moving apparatus 8. The moving apparatus 8 with the substrate 20 held by the substrate holder 7, moves within a plane along a direction (movement direction Y) perpendicular to the center line X from a position directly behind one shield plate 16a toward a position directly behind the other shield plate 16b. That is, the moving apparatus 8 moves the substrate 20, relative to the target 11 (see FIG. 1) and the shield plates 16a and 16b, along a direction transverse to the longitudinal axis (X direction) of the aperture 17.

In the embodiment, the shield plates 16a and 16b are secured parallel to the substrate 20, and the substrate 20 moves relative to the shield plates 16a and 16b while remaining parallel to them.

In the embodiment, the planar shape of the substrate 20 has a circular shape. Each of the planar shapes of the shield plates 16a and 16b is larger than that of the substrate. The width of the aperture 17 is shorter than the diameter of the substrate 20.

Accordingly, when the substrate 20 is at position “A” (shown in FIGS. 2A and 2B) directly behind the shield plates 16a and 16b, it is covered by taken such that the sputtered particles do not reach the deposition face 22 of the substrate 20. On the other hand, when a portion of the substrate 20, in moving from position A directly behind the shield plate 16a toward position “A” directly behind the shield plate 16b, is at position “B” (an incidence position “B”) directly behind the aperture 17, sputter particles that pass through the aperture 17 are incident on part of the deposition face 22 of the substrate 20.

The length of the aperture 17 along the center line X is greater than the diameter of the substrate 20. The substrate 20 moves such that it center passes through a center position of the aperture 17 along the center line X. When the center of the substrate 20 is at an incidence position “B”, the substrate 20 is exposed via the aperture 17 from one end along the center line X to another end. Therefore, when one end of the substrate 20 along the movement direction Y to another end passes through the incidence position “B”, sputtered particles reach the entire deposition face 22 of the substrate 20.

As described above, the substrate 20 is held at a diagonal position to the target 11, and the target 11 is arranged such that the sputter face 12 is diagonal with respect to the deposition face 22. The angle (incidence angle) between the incident direction of the sputtered particles and the deposition fare 22 of the substrate 20 is a small one of less than 90°. Therefore, orthrohombic crystals of the deposition material grow on the deposition face 22.

When the sputtered particles are incident to the deposition face 22 at this small incidence angle, the distance from the target 11 to the deposition face 22 is longer in the portion of the deposition face 22 further from the target 11 than in the portion closer to the target 11. Sputter particles that travel long distance are to be diffused. Therefore, the density of incident sputter particles is lower in the potion of the deposition face 22 further from the target 11.

As described above, the aperture 17 becomes narrower as it nears the target 11. The substrate 20 passes through the incidence position “B” at a constant speed. Therefore, the time one part of the substrate 20 passes across the aperture 17 at the incident position “B” decreases as the part nears the target 11.

That is, the portion of the substrate 20 that is far from the target 11 is exposed to low-density sputtered particles for a long time, and the portion of the substrate 20 that is near the target 11 is exposed to high-density sputtered particles for a short time. Eventually, an equal quantity of sputter particles reaches every position of the substrate 20, and a thin film having even thickness is deposited over the deposition face 22.

To form a thin film that is thicker than the thickness of a film deposited when the substrate 20 passes the incidence position “B” once, the substrate 20 is repeatedly moved from position “A” directly behind one shield plate 16a to position “A” directly behind the other shield plate 16b such that it passes through the incidence position “B” multiple times, whereby a thicker thin film can be obtained.

In the embodiment, a shield 26 for controlling incidence angle is provided between the target 11 and the shield 16. The shield 26 is plate-shaped, and includes a slit (aperture 27 for controlling incidence angle) that allow the sputtered particles to pass.

The size of the target 11 corresponds to the width of the ion beam 32. Sputtered particles having an angle spread are released toward the deposition face 22 from each ion beam inaction point on the target 11. The incident ion beam 32 has high intensity at the center of the target 11, and low intensity at the ends. According to the angle spread, the sputtered particles released from the target 11 contain particles that have high energy in relation to the direction toward the deposition face 22, and particles that have low energy.

Of the sputtered particles that travel with an angle spread from each ion irridation point on the target 11 toward the deposition face 22, the incidence angle of sputtered particles incident at the incidence position “B” is controlled by the shield 26 and the aperture 27. A maximum value θ5 of the incidence angle of sputtered particles that are incident to the deposition face 22 at incidence position “B” is restricted to no greater than 15°, and an expected incidence angle Δθ (the difference between the maximum value θ5 of the incidence angle and a minimum value thereof) is restricted to no greater than 10°.

In FIG. 1, the maximum incidence angle θ5 is the angle (incidence angle) formed between a line segment 29 extending from each point on the deposition face 22 over the deposition face 22 to the target 11, and is the incidence direction of the sputter particles. That is, in the embodiment, the shield 26 restricts the incidence angle of the sputtered particles at any point on the deposition face 22 (i.e. in the entire region of the deposition face 22) to no greater than 15°. Therefore, the incidence angle θ5 of the sputtered particles at, for example, a predetermined position at the approximate center of the deposition face, is restricted to no greater than 15°. By restricting the maximum incidence angle θ5 to no greater than 15°, the angle between the normal line of the deposition face 22 and the incidence direction of the sputter particles exceeds 75°.

Since the expected incidence angle Δθ is restricted, sputtered particles incident at incidence position “B” are limited to those ejected from a narrow range containing points where high energy sputter particles are ejected. Therefore, since sputtered particles having an energy value equal to or greater than a predetermined energy value are diagonally incident on the deposition face 22 at incidence position “B”, columnar particles accumulate on the deposition face 22 at a predetermined gradient thereto.

While the above explanation describes a case where Argon ions are ejected from the ion gun 30, the type of ions ejected from the ion gun 30 need only be one capable of sputtering the target 11, it being possible to use, for example, other types of rare gas ions such as Kr and Xe, molecular ions such as nitrogen and oxygen, neutral particles, cluster ions, etc.

There are no particular limitations on the shape of the ion beam 32, which can be any shape such as circular, sheet-like, elliptical, and polygonal.

The method of sputtering the target 11 is not limited to the ion beam sputtering method described above, and sputtering can be performed by evacuating the internal part of the vacuum chamber 2 while supplying a sputter gas, and then maintaining a vacuum atmosphere of a predetermined pressure inside the vacuum chamber 2 while applying a negative voltage to the target 11.

There are no particular limitations on the material used for the target 11. For example, if a target 11 of SiO2 is sputtered using the method described above, a diagonal columnar crystal film (an accumulated film of columnar particles having a predetermined gradient with respect to the deposition face 22) of silicon oxide (SiOx, x being an arbitrary integer) is deposited on the deposition face 22, and, when liquid crystal is contacted against this crystal film without performing surface processing such as rubbing and etching, the liquid crystal becomes orientated in a fixed direction.

A liquid crystal device can be obtained by using the step described above to form oriented films on deposition faces 22 of two substrates 20, and using liquid crystal to seal the space between the faces of the two substrates 20 where the oriented films are formed.

The deposition material for constituting the target 11 is not limited to SiO2, it being possible to use an inorganic material such as Al2O3 and ITO (Indium-tin-oxide), and mixtures of two or more types of such inorganic materials.

Reference symbol “A” in FIG. 1 represents an irradiation point where an irradiation axis 38 of the ion beam 32 intersects with the sputter face 12, and reference symbol “B” in FIG. 1 represents a deposition point that is an arbitrary position on the deposition face 22, at the center of the deposition face 22 in this embodiment.

The angle between the normal line 14 of the sputter face 12 passing through the irradiation point “A” and the irradiation axis 38 is deemed the irradiation angle θ1 of the deposition face 22, and is set at, for example, no less than 45° and no greater than 70°. In this case, the substrate 20 is arranged at a distance from the target 11 such that a positioning angle θ2, which is the angle between the normal line 14 and a line segment 28 that connects the deposition point “B” and the irradiation point “A”, is no less than 0° and no greater than 70°. The length of the line segment 28 that connects the irradiation point “A” and the deposition point “B” at the center of the deposition face 22 is deemed the substrate-target distance (TS-distance), and is, for example, 100 mm to 500 mm.

The angle between the line segment 28 that connects the deposition point “B” and the irradiation point “A” and the line segment 29 that extends from the deposition point “B” over the deposition face 22 to the target 11 side (i.e. the angle between the line segment 28 and the deposition face 22) is deemed a gradient angle θ3 of the substrate 20, and the substrate 20 is preferably tilted such that this gradient angle θ3 is no less tag and no greater than 15°.

Since the maximum incidence angle θ5 when sputtered particles from the target 11 are incident to the substrate 20 is no greater than 15°, a film having a columnar structure with excellent orientation can be formed. In addition, the distance between the target and the substrate can be made shorter than when using vapor deposition, facilitating migration of the deposition apparatus.

It is undesirable for the maximum incidence angle θ5 to exceed 15°, since this makes it difficult to form a columnar structure. If the maximum incidence angle θ5 is equal to or less than 10°, the individual columns have high independence and a film having a columnar she with excellent orientation is formed.

It is undesirable for the maximum incidence angle θ5 to be equal to or less than 1°, since, although a columnar structure is formed, orientation deteriorates due to comparatively large gaps between the columns; it is also undesirable with regard to industrial application since the deposition rate also deteriorates. When the maximum incidence angle θ5 is equal to or greater than 3°, the film structure becomes more compact and the deposition rate can be increased.

It is not essential to provide the shield 26 between the target 11 and the substrate 20, since the incidence angle of the sputtered particles incident on the deposition face 22 can be controlled by changing the TS-distance and the beam width.

For example, when the half bandwidth of the beam is 30 mm and the TS-distance is 300 mm, a maximum incidence angle θ5 of no greater than 15° can be ensured by making the gradient angle θ5 no greater than 15°, and the expected incidence angle Δθ can be reduced to no greater than 10° by increasing the TS-distance.

Even with the same TS-distance, the expected incidence angle Δθ decreases if the width of the ion beam 32 is narrow. Therefore, by reducing the beam width the expected incidence angle Δθ can be reduced to no greater than 10°. The expected incidence angle Δθ can also be reduced to no greater than 10° by increasing the TS-distance and reducing the beam width.

While a case where a film is deposited by sputtering of a target 11 is described above, this is not limitative of the invention.

For example, the invention also includes a case where vapor of deposition material is released into a vacuum chamber from an opening of a receptacle that contains the deposition material or from a liquid face (target) of the deposition material, a substrate is arranged in the vacuum chamber diagonally with respect to the target, the abovementioned shield for controlling film thickness is provided at a position of the subsume between the substrate and the target, and a film is deposited while moving the substrate with respect to the shield for controlling film thickness.

Similarly in this case, if the film is deposited while moving the substrate such that its target-side end passes through the narrow end of the shield for controlling film thickness, and the end of the substrate on the opposite side to the target passes through the wide end of the aperture for controlling film thickness, the deposition material can be deposited with an even thickness on the deposition face. Also, there are no particular limitations on the type of deposition material when the film is formed by vapor deposition.

While the above explanation describes a case where deposition is performed while moving only the substrate 20, the invention is not limited to this. If the shield 16 for controlling film thickness and the target 11 are secured in relation to each other and a fixed distance is maintained between the incidence position “B” and the target 11, it is possible to keep the substrate 20 secured and perform deposition while moving the shield 16 and the target 11 together, or to move the shield 16 and the target 11 while also moving the substrate 20.

Incidentally, when performing deposition using ion beam sputtering, the target 11 can be moved by moving the irradiation position of the ion beam 32 with the target 11 in a secured state, or by moving the irradiation position of the ion beam 32 together with the movement of the target 11.

While the above explanation describes a case where the substrate 20 moves between positions directly behind the shield plates 16a and 16b, the invention is not limited to this. Provided that the sputtered particles reach the deposition face 22 at locations other than the incidence position “B”, the substrate 20 can be passed through an end of the shield plate 16a on the opposite side to the aperture 17 to a position where the sputtered particles do not reach.

The shape of the substrate 20 is not limited to a circular shape. Provided that the length of a region for deposition (e.g. the deposition face 22) in the long direction of the aperture 17 is shorter than the length of the aperture 17, it is possible to use a substrate of various shapes such as rectangular, square, and elliptical.

There are no particular restrictions on the shape of the shield 16, it being possible to configure one shield plate as a shield, and then configure a shield for controlling film thickness by providing a slit having one wide end and one narrow end in the shield plate.

There are no particular restrictions on the shape of the aperture 17, and, as long as it is narrow on the target 11 side and wide on the opposite side to the target 11, it can be, for example, a fan-like shape. The width of the aperture 17 can be made gradually narrower as its distance to the target 11 decreases.

What is claimed is:

1. A deposition apparatus that uses sputtering to diagonally impact a substrate with particles emitted from a target and thereby forms a film on the substrate, comprising:
a first shield that blocks part of particles incident to the substrate;
a first aperture through which the particles pass, provided in the first shield, and being narrow near the target and wider away from the target; and
a moving apparatus that relatively moves between the substrate and the first aperture in a direction transverse to a longitudinal axis of the first aperture.

2. The deposition apparatus according to claim 1, wherein the first ampere has at least a shape substantially similar to an incidence region at the deposition face of the substrate.

3. The deposition apparatus according to claim 1, wherein the first aperture has a width being gradually extending along a direction away from the target.

4. The deposition apparatus according to claim 1, wherein an angle between a line segment that connects the target and the substrate, and the deposition face of the substrate, is no greater than 15°.

5. The deposition apparatus according to claim 1, wherein an angle between a line segment that connects the target and the substrate and the deposition face of the substrate, is no greater than 10°.

6. The deposition apparatus according to claim 4 or 5, wherein an angle between the line segment and the deposition face is not less than 1°.

7. The deposition apparatus according to claim 4 or 5, wherein an angle between the line segment and the deposition face is not less than 3°.

8. The deposition apparatus according to claim 1, further comprising:
a second shield that controls incidence angle of the particles, arranged between the first shield and the target; and
a second aperture provided in the second shield, and through which particles whose angle of incidence to the substrate is no greater than 15° pass.

9. The deposition apparatus according to claim 8, wherein the second aperture allows particles whose expected incidence is no greater than 10°, being a value obtained by subtracting a minimum value from a maximum value of the incidence angle, to pass.

10. A deposition method of using sputtering to diagonally impact a substrate with particles emitted from a target and thereby form a film on the substrate, comprising:
arranging a first shield between the target and the substrate, the first shield having a first aperture which is narrow near the target and wider away from the target; and
relatively moving between the substrate and the first aperture in a direction transverse to a longitudinal axis of the first aperture.

11. The deposition method according to claim 10, wherein the maximum incidence angle when particles from the target are incident to the substrate is no greater than 15°.

12. The deposition method according to claim 10, wherein the maximum incidence angle when particles from the target are incident to the substrate is no greater than 10°.

13. The deposition method according to claims 11 or 12, wherein the maximum incidence angle is no less than 1°.

14. The deposition method according to claims 11 or 12, wherein the maximum incidence angle is no less than 3°.

15. The deposition method according to claim 10, wherein an expected incidence angle, being a value obtained by subtracting a minimum incidence angle when the particles are incidence to the substrate, from the maximum incidence angle, is no greater than 10°.
